(19) United States
(12) Patent Application Publication
(10) Pub. No.: US 2019/0335609 A1
(43) Pub. Date: Oct. 31, 2019

(54) TURBO FAN

(71) Applicant: Cambricon Technologies Corporation Limited, Beijing (CN)

(72) Inventors: Kun LI, Beijing (CN); Dejing WANG, Beijing (CN); Shuo XING, Beijing (CN)

(21) Appl. No.: 16/385,664

(22) Filed: Apr. 16, 2019

(30) Foreign Application Priority Data
Apr. 28, 2018 (CN) 201810404929.9

(51) Int. Cl. H05K 7/20

(52) U.S. Cl. CPC H05K 7/2019; F04D 25/064; H05K 7/20172

(57) ABSTRACT

Disclosed is a turbo fan including a rotor housing and a fan blade structure. The fan blade structure is arranged around the rotor housing and fixed to the periphery of the rotor housing and includes multiple spaced fan blades extending in the same direction. A section of the fan blade is an arc and the length of the arc is ⅛-⅙ of the circumference of a circle in which the arc is located. The turbo fan sets the fan blade with an arc section, and when the turbo fan rotates in the direction corresponding to a recess of the fan blade, the arc structure of the fan blade can push more air to increase air volume.

### TECHNICAL FIELD

The present disclosure relates to the field of heat dissipation, and particularly relates to a turbo fan.

### BACKGROUND

In recent years, the breakthrough in artificial intelligence has brought earth-shaking changes to the information industry. Accelerator cards based on ASIC chips and FPGA chips have achieved faster data acquisition, data processing, classification and prediction through a plurality of artificial intelligence algorithms, especially machine learning algorithms. The accelerator cards have achieved an order of magnitude reduction in computing time. Higher requirements are also placed on hardware computing power, but the improvements of computing power correspondingly increase power consumption of board cards. Limited contact area between heat dissipation structure of a board card and the external world puts forward higher requirements for air volume, wind pressure and low noise of a fan.

At present, there are two kinds of board card cooling fans: axial fans and turbo fans. Cooling performance of fans mainly depends on their air volume and wind pressure, while traditional turbo fans need to increase rotating speed of fans to increase air volume, thus exacerbating noise. In this case, large air volume and low noise may not be compromised at the same time.

### SUMMARY

In view of this, it is necessary to provide a turbo fan to overcome the problem in traditional turbo fans being unable to simultaneously take large air volume and low noise into account.

A turbo fan includes:

a rotor housing; and

a fan blade structure arranged around the rotor housing and fixed to a periphery of the rotor housing, and the fan blade structure includes a plurality of fan blades spaced and extending in the same direction, where a cross section of the fan blade is arc-shaped, and the length of the arc is ⅛-⅙ of a circumference of a circle in which the arc is located.

In one embodiment, the rotor housing includes:

an accommodation bucket, forming a fan rotor accommodation space around to accommodate fan rotors; and

an annular connecting plate fixedly connected to an outer edge of the accommodation bucket, and the fan blade structure arranged around the annular connecting plate and fixedly connected with the annular connecting plate.

In one embodiment, the accommodation bucket includes:

a top plate of accommodation bucket;

a side plate of accommodation bucket, arranged around an edge of the top plate of accommodation bucket and fixedly connected with the edge of the top plate of accommodation bucket, the annular connecting plate fixedly arranged at a side of the side plate of accommodation bucket away from the top plate of accommodation bucket.

In one embodiment, the accommodation bucket further includes a plurality of heat-dissipation holes arranged on a surface of the accommodation bucket.

In one embodiment, the turbo fan further includes an annular bracket arranged around the rotor housing, and the annular bracket is fixedly connected to the plurality of fan blades.

In one embodiment, the annular bracket is arranged at an end of the fan blade away from the annular connecting plate.

In one embodiment, a diameter of a circle in which an arc-shaped cross section of the fan blade is located is 1/10-⅙ of an outer diameter of the fan blade structure.

In one embodiment, the axis of the fan blade is perpendicular to the annular connection plate.

In one embodiment, two ends of the arc are respectively an air inlet arranged near the rotor housing and an air outlet arranged away from the air inlet, where the air inlet is blade-shaped.

In one embodiment, an angle between a tangential line of the arc at the air outlet and a tangent line of the fan blade structure at the air outlet is acute.

In one embodiment, the air outlet is perpendicular to a tangent line of the outer edge of the fan blade structure at the air outlet.

In one embodiment, the turbo fan further includes an installation chassis, the installation chassis and the rotor housing are oppositely and rotatably connected. The installation chassis includes an installation plate and a side panel arranged in a periphery of the installation plate, where the side panel and the installation plate form a groove around. The side panel is arranged with a wire passing groove.

In one embodiment, the turbo fan further includes a fan terminal, and the fan terminal includes:

a connecting arm, an end of the connecting arm fixedly connected to the side panel; and

a wire pressing arm, an end of the wire pressing arm fixedly connected to another end of the connecting arm away from the side panel and another end of the wire pressing arm spaced with the side panel. The wire pressing arm and the connecting arm are located on the same plane as the installation plate. A surface of the wire pressing arm away from the rotor housing is arranged with a wire pressing groove, and the wire pressing groove is arranged corresponding with the wire passing groove.

The embodiments of the present disclosure provide a turbo fan including a rotor housing and a fan blade structure connected with the rotor housing. The turbo fan arranges the fan blade with an arc-shaped cross section, and when the turbo fan rotates, the arc structure of the fan blade can push more air to increase air volume. Furthermore, since the arc length is ⅛-⅙ of the circumference of the circle where the arc is located, the fan blade has an appropriate radian, thus effectively reducing wind resistance and then effectively reducing noise and increasing air volume.

### BRIEF DESCRIPTION OF THE DRAWINGS

FIG. 1 is a structural diagram of a turbo fan according to an embodiment of the present disclosure.

FIG. 2 is a top view of a turbo fan according to an embodiment of the present disclosure.

FIG. 3 is a diagram showing test effects of air volume and wind pressure of a turbo fan according to an embodiment of the present disclosure

FIG. 4 is a partial enlargement diagram of circle A area in FIG. 2.

FIG. 5 is a top view of a turbo fan according to another embodiment of the present disclosure.

FIG. 6 is a bottom view of a turbo fan according to an embodiment of the present disclosure.

FIG. 7 is a diagram of the exploded structure of a turbo fan according to an embodiment of the present disclosure.

FIG. 8 is a partial enlargement diagram of circle B area in FIG. 7.

### DESCRIPTION OF REFERENCE NUMBERS IN THE ACCOMPANIED DRAWINGS

10 Turbo Fan

100 Rotor Housing

110 Accommodation Bucket

112 Top Plate of Accommodation Bucket

114 Side Plate of Accommodation Bucket

116 Heat Dissipation Hole

120 Annular Connecting Plate

200 Fan Blade Structure

210 Fan Blade

212 Air Intake

214 Air Output

300 Annular Bracket

400 Installation Chassis

410 Installation Plate

420 Side panel

422 Wire Passing Groove

500 Fan Terminal

510 Connecting Arm

520 Wire Pressing Arm

522 Wire Pressing Groove

### DETAILED DESCRIPTION OF THE EMBODIMENTS

To make the above purposes, features and advantages of the present disclosure clearer and easier to understand, specific embodiments of the present disclosure will be described in detail hereinafter with reference to the accompanied drawings. Details are described below to make the present disclosure fully understood. However, the present disclosure may be implemented in other ways and those skilled in the art can make similar improvements without departing from the scope of the present disclosure, and thus the present disclosure is not limited by the specific embodiments disclosed below.

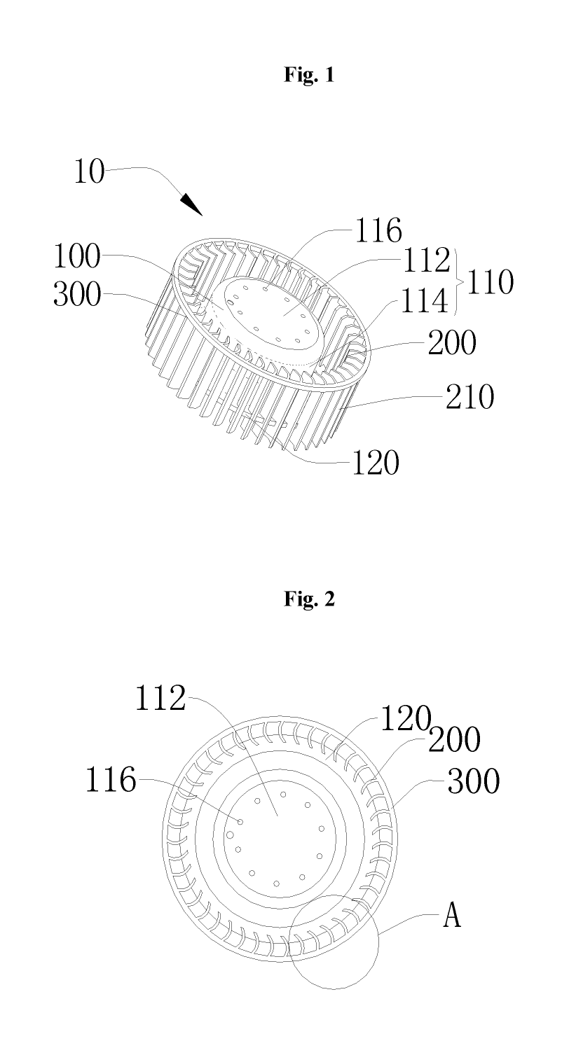

Referring to FIG. 1 and FIG. 2, the present disclosure provides a turbo fan 10 including a rotor housing 100 and a fan blade structure 200 arranged around the rotor housing 100. The fan blade structure 200 is fixed to the periphery of the rotor housing 100 and includes a plurality of fan blades 210 spaced and extending in the same direction. Alternatively, the plurality of fan blades 210 of the fan blade structure 200 are centrally symmetrical with respect to the axis of the rotor housing 100. The arc length of a cross section of the fan blade 210 is ⅛-⅙ of the circumference of the circle in which the arc is located. It is understandable that a central angle corresponding to the arc lie between 45 to 60 degrees. The shape of the fan blade 210 is a “tile” type and a cross section of the “tile” is an arc, the arc length is ⅛-⅙ of the circumference of the circle in which the arc is located. In one embodiment, the length of the arc is 1/7 of the circumference of the circle in which the arc is located.

In the present embodiment, the turbo fan 10 sets the fan blade 210 with an arc section, and when the turbo fan 10 rotates, the arc structure of the fan blade 210 can push more air to increase air volume. Meanwhile, since the length of the arc is ⅛-⅙ of the circumference of the circle where the arc is located, the fan blade 210 has an appropriate radian, thus effectively reducing wind resistance and then effectively reducing noise and increasing air volume.

The material of the rotor housing 100 is not limited as long as the shape can be maintained. Alternatively, the material of the rotor housing 100 can be a metal or chemical product. For example, the material of the rotor housing 100 can be aluminum or aluminum alloy. Alternatively, a section of the rotor housing 100 can be circular. The material of the fan blade 210 is not limited as long as the shape can be maintained. Alternatively, the material of the fan blade 210 can be a metal or a chemical product. For example, the material of the fan blade 210 can be aluminum or aluminum alloy. In one embodiment, the fan blade structure 200 is integrated with the rotor housing 100, thus the overall structure is more stable.

In one embodiment, the rotor housing 100 includes an accommodation bucket 110 and an annular connecting plate 120 fixedly connected with the outer edge of the accommodation bucket 110, where the accommodation bucket 110 forms a fan rotor accommodation space around to accommodate fan rotors, and the fan blade structure 200 is arranged around the annular connecting plate 120 and fixedly connected with the annular connecting plate 120. Alternatively, the fan blade structure 200 can be spaced with the accommodation bucket 110. Alternatively, the fan blade structure 200 can be fixedly connected to the accommodation bucket 110.

Alternatively, the annular connection plate 120 is perpendicular to the axis of the accommodation bucket 110. Alternatively, a connection between the annular connecting plate 414 and the accommodation bucket 412 is arranged in an arc shape, thereby reducing wind resistance and noise. In one embodiment, the accommodation bucket 412 is integrated with the annular connecting plate 414, and the structure is stable.

Alternatively, the accommodation bucket 110 includes a top plate of accommodation bucket 112 and a side plate of accommodation bucket 114. The side plate of accommodation bucket 114 is arranged around the edge of the top plate of accommodation bucket 112 and fixedly connected to the edge of the top plate of accommodation plate 112. The annular connecting plate 120 is fixedly arranged at one side of the side plate of accommodation bucket 114, and the side is away from the top plate of accommodation bucket 112. When the turbo fan 10 rotates, air current flows through the side plate of accommodation bucket 114 from the top plate of accommodation bucket 112 to the annular connecting plate 120.

In one embodiment, the accommodation bucket 110 further includes a plurality of heat-dissipation holes 116 and the plurality of heat-dissipation holes 116 are arranged at the surface of the accommodation bucket 110. Alternatively, the plurality of heat-dissipation holes 116 may be disposed on the top plate of accommodation bucket 112, thus dissipating heat generated by rotors in the rotor housing 100 faster. Alternatively, the plurality of heat-dissipation holes 116 may be disposed on the side plate of accommodation bucket 114. In one embodiment, the heat-dissipation holes 116 can be equally spaced and the shape of the heat-dissipation holes 116 is not limited. Alternatively, the shape of the heat-dissipation holes 116 may be circular or polygonal. Specifically, the shape of the heat-dissipation holes 116 may be triangle, quadrilateral or hexagon. In the present embodiment, the heat-dissipation holes 116 may be through holes that penetrate the inner part of the rotor housing 410 to facilitate dissipating heat from rotors.

In one embodiment, the turbo fan 10 further includes an annular bracket 300 arranged around the rotor housing 100. The annular bracket 300 is fixedly connected with the plurality of fan blades 210. Alternatively, the annular bracket 300 is fixedly connected with all the fan blades 200 within the fan blade structure 210. Alternatively, the annular bracket 300 is integrated with the fan blade structure 200. In the present embodiment, the annular bracket 300 makes the fan blade structure 200 more stable and avoids noise caused by the shaking of the fan blade 210.

In one embodiment, the annular bracket 300 is arranged at an end of the fan blade 210 away from the annular connecting plate 120. The two ends of the fan blade 210 in the vertical direction of the annular connecting plate 120 are respectively fixed, so as to make the fan blade structure 200 more stable and avoid noise caused by the shaking of the fan blade 210.

In one embodiment, the diameter of a circle in which an arc-shaped cross section of the fan blade 210 is located is 1/10-⅙ of an outer diameter of the fan blade structure 200. Alternatively, the diameter of the circle in which the arc-shaped cross section of the fan blade 210 is located may be 1/9 of the outer diameter of the fan blade structure 200. Alternatively, the diameter of the circle in which the arc-shaped cross section of the fan blade 210 is located may be ⅛ of the outer diameter of the fan blade structure 200. Alternatively, the diameter of the circle in which the arc-shaped cross section of the fan blade 422 is located may be 1/7 of the outer diameter of the fan blade structure 200. In one embodiment, the diameter of the circle in which the arc-shaped cross section of the fan blade 210 is located can be 6.6 mm, the outer diameter of the fan blade structure 420 can be 66 mm.

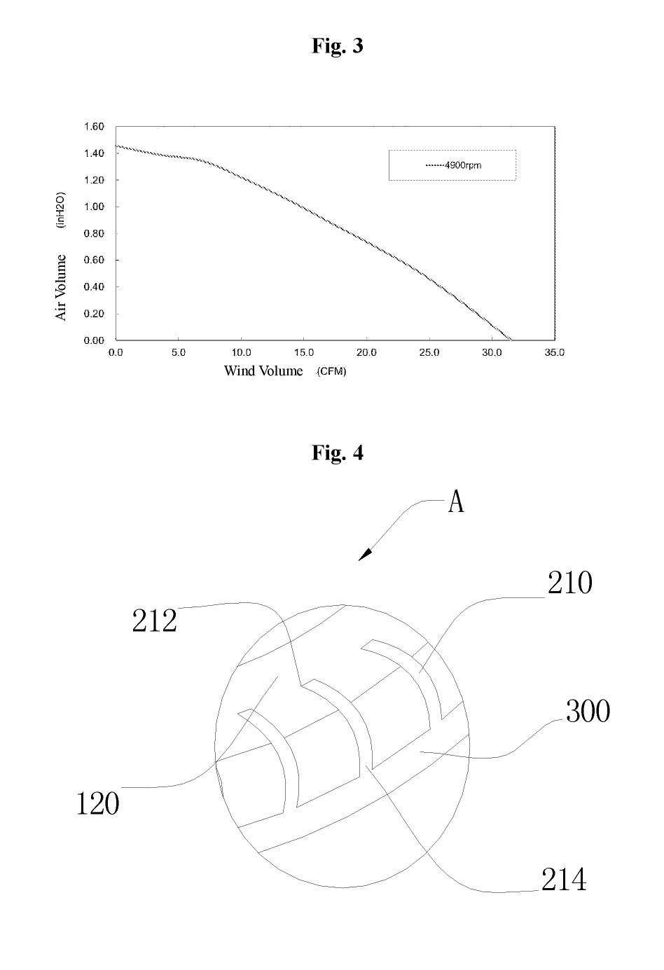

In the present embodiment, the size of the fan blade 210 is in proportion to that of the turbo fan 10 and the overall compatibility is better, so that the condition of air inlet and air outlet is more balanced. In this case, the air volume and wind pressure at the air outlet of the turbo fan 10 can achieve an ideal result (see FIG. 3). In one embodiment, the rotational speed of the turbo fan 10 can be 4900 rpm.

In one embodiment, the axis of the fan blade 210 along the longitudinal direction of the fan blade can be perpendicular to the annular connection plate 120. It is understandable that the fan blade 210 is integrally perpendicular to the annular connecting plate 120, so that the outlet direction of the turbo fan 10 is parallel to the annular connecting plate 120. Alternatively, the fan blade 210 can be inclined to the surface of the annular connection plate 120. The arc-shaped fan blade 210 has a recess surface and a projection surface opposite to the recess surface. When an angle between the recess surface of the fan blade 210 and a surface of annular connecting plate 120 near the top plate of accommodation bucket 112 is acute, the outlet direction of the turbo fan 10 is concentrated in the direction close to the annular connecting plate 120. When the angle between the recess surface of the fan blade 210 and a surface of annular connecting plate 120 near the top plate of accommodation bucket 112 is obtuse, the outlet direction of the turbo fan 10 is concentrated in the direction away from the annular connecting plate 120.

Referring to FIG. 4, in one embodiment, the two ends of the arc of the fan blade are an air inlet 212 arranged near the rotor housing 200 and an air outlet 214 away from the air inlet 212 respectively, where the air inlet 212 is blade-shaped. The air current generated by rotation of the turbo fan 10 flows into the fan blade structure 200 from the air inlet 212 and flows out of the fan blade structure 200 from the air outlet 214. The air inlet 212 is configured to intercept the air current entering the fan blade structure 200 during the rotation of the fan blade structure 200. In the present embodiment, the air inlet 212 is arranged to be blade-shaped to reduce wind resistance and facilitate intercepting air current, thereby reducing noise.

In one embodiment, an angle between a tangential line of the arc at the air outlet 214 and a tangent line of the fan blade structure 200 at the air outlet 214 is acute. In one embodiment, the angle may lie between 30 to 60 degrees. Alternatively, the angle may be 45 degrees.

In the present embodiment, the angle between a tangential line of the arc at the air outlet 214 and a tangent line of the fan blade structure 200 at the air outlet 214 is acute, so that the axis of the fan blade 210 is close to the axis of the rotor housing 200. The fan blade 210 with such an angle may facilitate the air current to be generated and accelerated by the fan blade 210, thus accelerating outflow speed and increasing air volume.

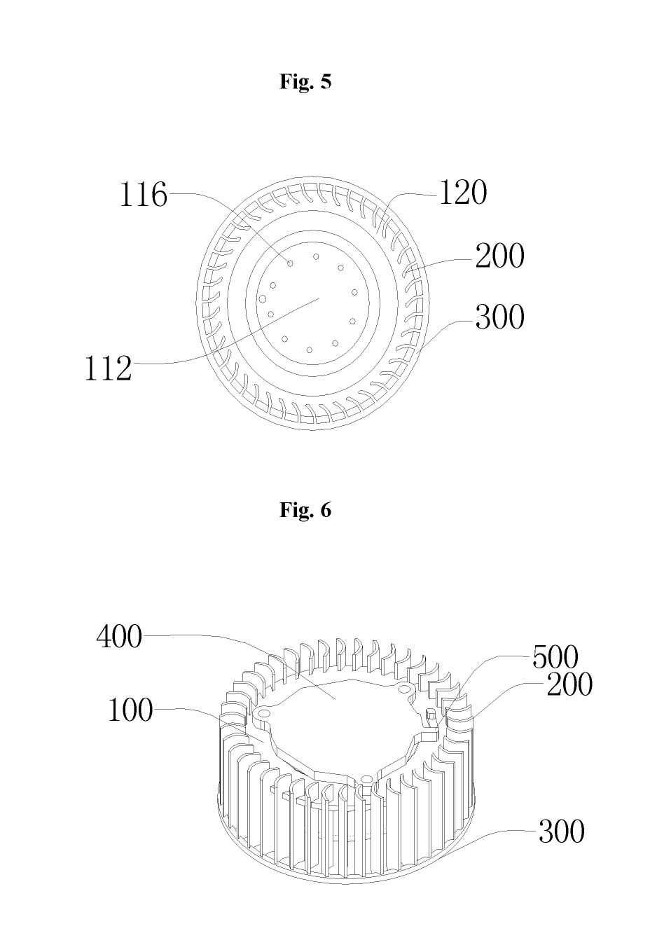

Referring to FIG. 5, in one embodiment, the annular bracket 300 is arranged at the air outlet 214 and the end of the fan blade 210 away from the annular connecting plate 120. When the air current flows out, the annular bracket 300 can act as a barrier to prevent the air current from flowing away from the annular connecting plate 120. In one embodiment, the air outlet 214 is perpendicular to a tangent line of the outer edge of the fan blade structure 200 at the air outlet 214 to facilitate the air in the turbo fan 10 to flow out.

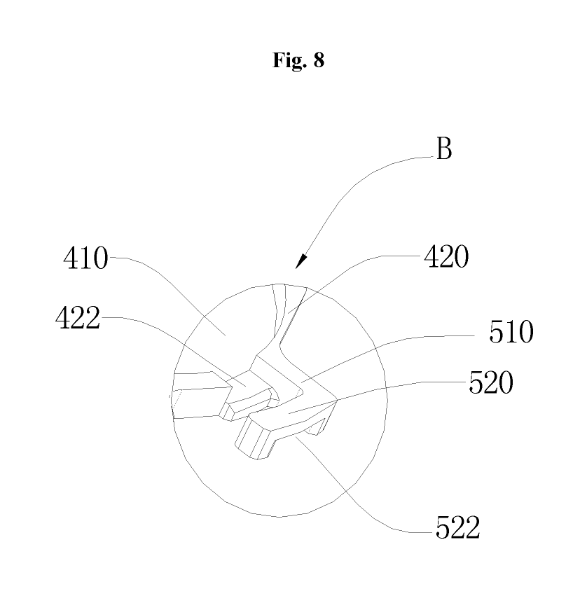

Referring to FIG. 6, in one embodiment, the turbo fan 10 further includes an installation chassis 400, and the installation chassis 400 and the rotor housing 100 are oppositely and rotatably connected. The installation chassis 400 includes an installation plate 410 and a side panel 420 arranged in the periphery of the installation plate 410, where the side panel 420 and the installation plate 410 form a groove. As shown in FIG. 8, the side panel 420 is arranged with a wire passing groove 422.

In one embodiment, the installation chassis 400 is fixedly installed on an installation surface. The installation chassis 400 and the installation surface can be fixedly connected by screws. Specifically, three screw holes are equally spaced in the periphery of the installation chassis 400, and the installation chassis 400 is connected with the installation surface by screws passed through the screw holes. The material of the installation chassis 400 is not limited as long as the shape can be maintained. Alternatively, the installation chassis 400 may be metal. Specifically, the installation chassis 400 can be aluminum or aluminum alloy to facilitate heat dissipation of the turbo fan 10. The shape of the installation chassis 400 is not limited. In one embodiment, the shape of the installation chassis 400 can be a circular plate or a polygonal plate.

In one embodiment, a plurality of cutting edges are spaced in the side panel 420 to make the installation chassis 400 irregularly circular, thus avoiding the problem that the installation chassis 400 cannot be installed due to a size error during the production process. In one embodiment, the side panel 420 is perpendicular to the installation plate 410. The groove formed by the side panel 420 and the installation plate 442 is configured to accommodate rotors and the wire passing groove 422 is configured to allow wires connecting the rotors to pass through for assembly. The installation chassis 400 is arranged with a shaft at the axis on the side of the rotor housing 100, and a fan rotor is installed on the shaft and can rotate around the shaft.

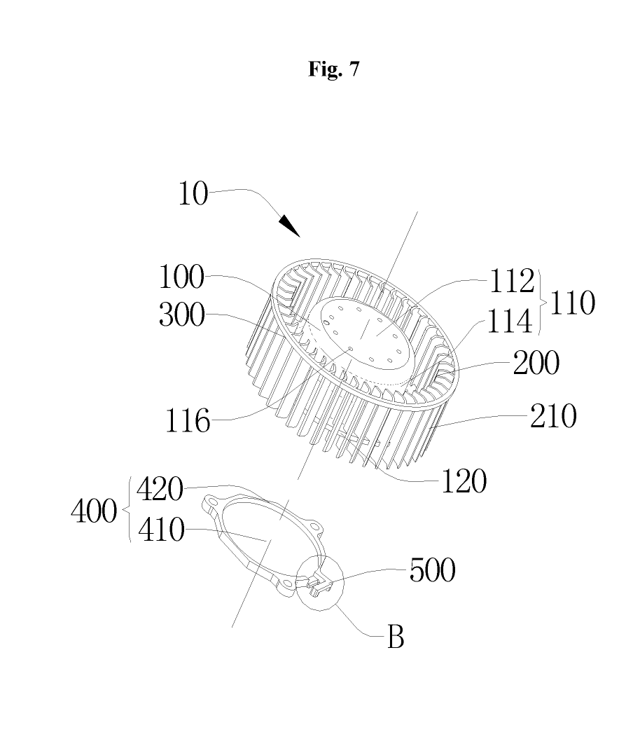

Referring to FIG. 6 and FIG. 7, in one embodiment, the turbo fan 10 further includes a fan terminal 500, and the fan terminal 500 is configured to protect connecting wires of the turbo fan 10. The fan terminal 500 includes a connecting arm 510 and a wire pressing arm 520. An end of the connecting arm 510 is fixedly connected with the side panel 420, which is fixedly connected with the end of the connecting arm 510 away from the side panel 420, and the other end of the connecting arm 510 is spaced with the side panel 420. The wire pressing arm 520 and the connecting arm 510 are located on the same plane as the installation plate 420. A surface of the wire pressing arm 520 away from the rotor housing 100 is arranged with a wire pressing groove 522, and the wire pressing groove 522 is arranged corresponding with the wire passing groove 422.

In one embodiment, the wire pressing arm 520 forms an L-shape with the connecting arm 510. Alternatively, the shape of the fan terminal 500 can also be annular. An interval between the wire pressing arm 520 and the side panel 420 forms an opening, and the opening facilitates the connecting wires to pass through and then enter the fan terminal 500. The wire pressing groove 522 can form an interval between the fan terminal 500 and the base 100 so as to facilitate the connecting wires to pass through. In one embodiment, the fan terminal 500 is integrated with the installation chassis 400. In one embodiment, the fan terminal 500 is as thick as the installation chassis 400.

In the present embodiment, the connecting wires are led from the wire passing groove 422 to the wire pressing groove 522 and are then led out, so as to protectively enclose the connecting wires and avoid influencing the connecting wires when the turbo fan 10 rotates, thus preventing interference.

Technical features of the above-mentioned embodiments may be arbitrarily combined. For the sake of concise description, not all possible combinations of the technical features in the above-mentioned embodiments are described. However, as long as there is no contradiction between the combinations of the technical features, the combination should be considered within the scope of the present specification.

The described embodiments merely introduce some implementations of the present disclosure and the description is specific, but the embodiments should not be considered as limitations to the scope of the present disclosure. It should be noted that modifications and improvements made by those of ordinary skill in the art without departing from the present disclosure shall fall within the protection scope of the present disclosure. Therefore, the protection scope of the present disclosure shall be subject to the claims.

What is claimed is:

1. A turbo fan, comprising:
a rotor housing; and
a fan blade structure arranged around the rotor housing and fixed to a periphery of the rotor housing, and the fan blade structure comprising a plurality of fan blades spaced and extending inward, wherein a cross section of the fan blade is an arc and a length of the arc is ⅛-⅙ of a circumference of a circle in which the arc is located.

2. The turbo fan of claim 1, wherein the rotor housing comprises:
an accommodation bucket, forming a fan rotor accommodation space around to accommodate a fan rotor; and
an annular connecting plate fixedly connected with an outer edge of the accommodation bucket, and the fan blade structure arranged around the annular connecting plate and fixedly connected with the annular connecting plate.

3. The turbo fan of claim 2, wherein the accommodation bucket comprises:
a top plate of accommodation bucket; and
a side plate of accommodation bucket arranged around the edge of the top plate of accommodation bucket and fixedly connected with an edge of the top plate of accommodation bucket, the annular connecting plate fixedly arranged at a side of the side plate of accommodation bucket away from the top plate of accommodation bucket.

4. The turbo fan of claim 2, wherein the accommodation bucket further comprises a plurality of heat-dissipation holes arranged on a surface of the accommodation bucket.

5. The turbo fan of claim 1, wherein the turbo fan further comprises an annular bracket arranged around the rotor housing, and the annular bracket is fixedly connected with the plurality of fan blades.

6. The turbo fan of claim 5, wherein the annular bracket is arranged at an end of the fan blade away from the annular connecting plate.

7. The turbo fan of claim 1, wherein a diameter of a circle in which an arc-shaped cross section of the fan blade is located is 1/10-⅙ of an outer diameter of the fan blade structure.

8. The turbo fan of claim 2, wherein the axis of the fan blade along the longitudinal direction of the fan blade is perpendicular to the annular connection plate.

9. The turbo fan of claim 1, wherein two ends of the arc of the fan blade are an air inlet arranged near the rotor housing and an air outlet away from the air inlet respectively, the air inlet is blade-shaped.

10. The turbo fan of claim 9, wherein an angle between a tangential line of the arc at the air outlet and a tangent line of the fan blade structure at the air outlet is acute.

11. The turbo fan of claim 9, wherein the air outlet is perpendicular to a tangent line of the outer edge of the fan blade structure at the air outlet.

12. The turbo fan of claim 1, wherein the turbo fan further comprises an installation chassis, the installation chassis and the rotor housing are rotatably connected, the installation chassis comprising:
an installation plate; and
a side panel arranged in a periphery of the installation plate, wherein the side panel and the installation plate form a groove around; the side panel is arranged with a wire passing groove.

13. The turbo fan of claim 12, wherein the turbo fan further comprises a fan terminal, and the fan terminal comprising:
a connecting arm, an end of the connecting arm fixedly connected with the side panel; and
a wire pressing arm, an end of the wire pressing arm fixedly connected with another end of the connecting arm away from the side panel, and another end of the wire pressing arm spaced with the side panel; wherein the wire pressing arm and the connecting arm are located at a same plane as the installation plate; a surface of the wire pressing arm away from the rotor housing is arranged with a wire pressing groove, and the wire pressing groove is arranged corresponding to the wire passing groove.
